(19) United States
(12) Patent Application Publication
(10) Pub. No.: US 2012/0199977 A1
(43) Pub. Date: Aug. 9, 2012

(54) SEMICONDUCTOR DEVICE

(76) Inventor: Sukehiro YAMAMOTO, Chiba-shi (JP)

(21) Appl. No.: 13/362,678

(22) Filed: Jan. 31, 2012

(30) Foreign Application Priority Data
Feb. 7, 2011 (JP) 2011-024241

(51) Int. Cl. H01L 23/485

(52) U.S. Cl. 257/762; 257/763; 257/E23.02

(57) ABSTRACT

To prevent generation of cracks in an insulating film provided under a bonding pad, a semiconductor device includes a three-layered bonding pad, and the three-layered bonding pad includes a first metal film, a second metal film, and a third metal film, in which the second metal film has a Young's modulus higher than a Young's modulus of the first metal film and a Young's modulus of the third metal film.

### BACKGROUND OF THE INVENTION

1. Field of the Invention

The present invention relates to a semiconductor device having a bonding pad.

2. Description of the Related Art

A conventional semiconductor device having a bonding pad is explained. A bonding pad is provided to a semiconductor device for supplying a power supply voltage and a ground potential to a semiconductor integrated circuit, or exchanging data with external devices. FIG. 5 is a schematic cross-sectional view illustrating a vicinity of a bonding pad of a conventional semiconductor device having a bonding pad.

A first metal film 51 is provided on an insulating film 53 provided on the surface of a semiconductor substrate 50. A second metal film 52 is provided directly over the first metal film 51. A protective film 54 covers over the second metal film 52, and has an opening portion above a bonding pad. The protective film 54 covers the second metal film 52 other than the opening portion of the protective film 54. Accordingly, the opening portion of the protective film 54 defines a region to be used as the bonding pad.

Regarding the Young's moduli as physical properties of the first metal film 51 and the second metal film 52, the Young's modulus of the first metal film 51 is higher than that of the second metal film 52. This structure enhances durability of the vicinity of the bonding pad with respect to stress generated by impact of wire bonding since the first metal film 51 having a higher Young's modulus is provided as the underlayer of the bonding pad (see, for example, Japanese Patent Application Laid-open No. 2009-027098).

In the conventional technology, however, depending on the magnitude of stress generated by impact of wire bonding, the second metal film 52 and the first metal film 51 both strain to generate cracks in the insulating film 53, which has been a problem.

### SUMMARY OF THE INVENTION

The present invention has been made in view of the above-mentioned problem, and it is an object thereof to provide a semiconductor device capable of preventing generation of cracks in an insulating film provided under a bonding pad.

In order to solve the above-mentioned problem, the present invention provides a semiconductor device having a bonding pad, including: a first metal film provided on an insulating film provided on a semiconductor substrate; a second metal film provided on the first metal film; a third metal film provided on the second metal film; and a protective film including an opening portion above the third metal film, and covering the first metal film, the second metal film, and the third metal film at portions excluding the opening portion, in which the second metal film has a Young's modulus higher than a Young's modulus of the first metal film and a Young's modulus of the third metal film.

According to the present invention, the three-layered bonding pad including the first metal film, the second metal film, and the third metal film is used, and the second metal film has a Young's modulus higher than the Young's moduli of the first metal film and the third metal film. This structure can prevent generation of cracks in the insulating film provided under the bonding pad.

### BRIEF DESCRIPTION OF THE DRAWINGS

In the accompanying drawings:

FIG. 1 is a schematic cross-sectional view illustrating a semiconductor device according to an embodiment of the present invention;

FIGS. 2A and 2B are schematic cross-sectional views illustrating strain in films caused by wire bonding;

FIG. 3 is a schematic cross-sectional view illustrating a semiconductor device according to Modified Example 1 of the embodiment of the present invention;

FIG. 4 is a schematic cross-sectional view illustrating a semiconductor device according to Modified Example 2 of the embodiment of the present invention; and

FIG. 5 is a schematic cross-sectional view illustrating a conventional semiconductor device.

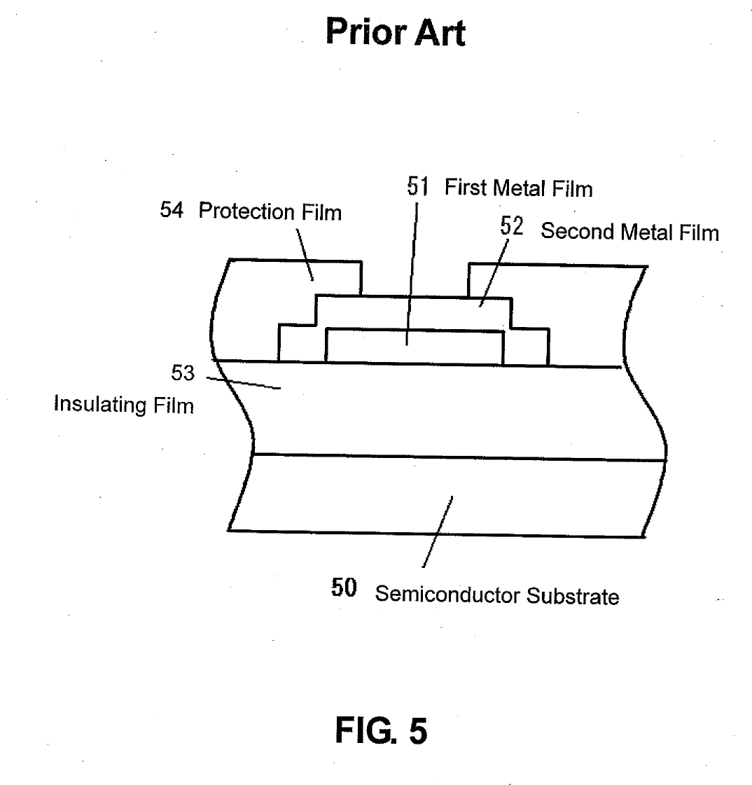

### DETAILED DESCRIPTION OF THE PREFERRED EMBODIMENT

Hereinafter, an embodiment of the present invention is described with reference to the accompanying drawings.

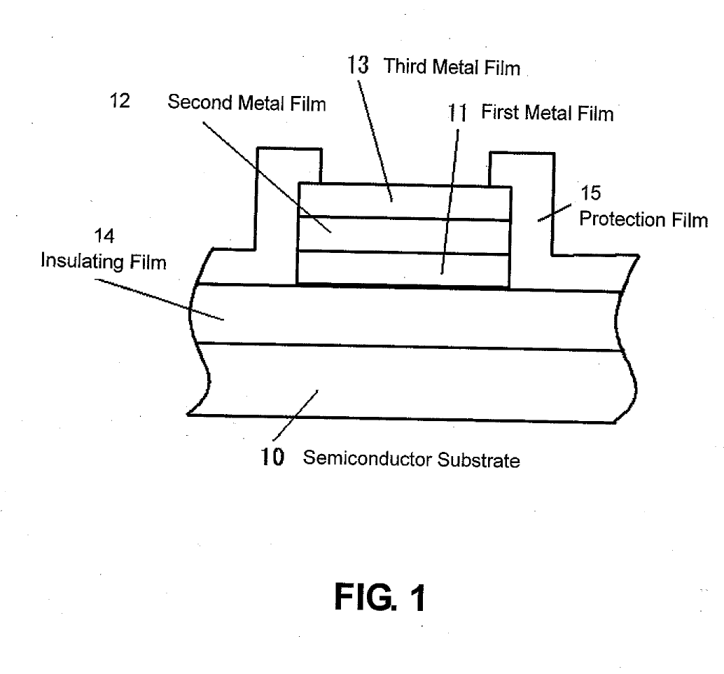

First, the structure of a semiconductor device having a bonding, pad is described. FIG. 1 is a schematic cross-sectional view illustrating a semiconductor device according to the embodiment of the present invention.

A first metal film 11 is provided on an insulating film 14 provided on the surface of a semiconductor substrate 10. A second metal film 12 is provided on the first metal film 11. A third metal film 13 is provided on the second metal film 12. Further, a protective film 15 including an opening portion is provided on the third metal film 13 and the insulating film 14. The opening portion of the protective film 15 defines a region of the bonding pad. The protective film 15 covers the first metal film 11, the second metal film 12, and the third metal film 13 at portions excluding the opening portion thereof. The size of the opening portion determines a region that can be used as the bonding pad, and is smaller than the sizes of the first metal film 11, the second metal film 12, and the third metal film 13. The first metal film 11 and the third metal film 13 can be formed of aluminum, for example, and the second metal film 12 can be formed of copper or tungsten. The Young's modulus of aluminum is approximately 70 GPa, the Young's modulus of copper is approximately 120 GPa, and the Young's modulus of tungsten is approximately 400 GPa. In this structure, the Young's modulus of the second metal film 12 is higher than the Young's moduli of the first metal film 11 and the third metal film 13.

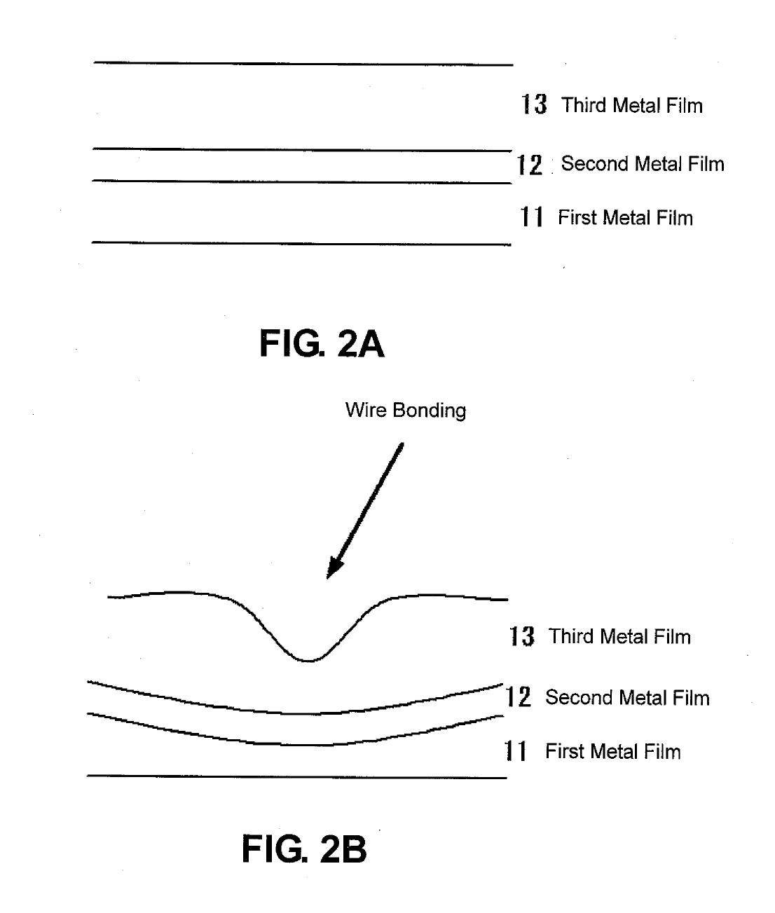

Next, strain in the films forming the bonding pad is described, which is caused when wire bonding is performed on the bonding pad. FIGS. 2A and 2B are schematic cross-sectional views illustrating the strain in the films caused by wire bonding.

Before wire bonding is performed on the bonding pad, as illustrated in FIG. 2A, the first metal film 11, the second metal film 12, and the third metal film 13 are substantially parallel to one another and are flatly overlapped.

When wire bonding is performed on the bonding pad, as illustrated in FIG. 2B, the third metal film 13 having a low Young's modulus greatly strains due to stress generated by impact of the wire bonding, with the center as an impact point of the wire bonding (note that, FIG. 2B is an image view exaggerating the strain). At this time, because the second metal film 12 has a higher Young's modulus than that of the third metal film 13, the stress due to the strain in the third metal film 13 is dispersed mainly in a planar direction rather than in a direction perpendicular to the second metal film 12. The second metal film 12 thus strains substantially uniformly, though the second metal film 12 strains rather greatly with the center as the impact point of wire bonding. The stress due to the strain in the second metal film 12 is absorbed by the first metal film 11 having a low Young's modulus. Accordingly, the bottom surface of the first metal film 11, namely a bonding surface between the first metal film 11 and the insulating film 14, hardly strains, and hence the impact of wire bonding hardly affects the insulating film 14. As a result, cracks are further prevented from being generated in the insulating film 14.

In this way, by employing a three-layered bonding pad including the first metal film 11, the second metal film 12 having a Young's modulus lower than the Young's moduli of the first metal film 11 and the third metal film 13, and the third metal film 13, it is possible to prevent cracks from being generated in the insulating film 14 provided under the bonding pad.

Note that, the undermost layer of the bonding pad is the first metal film in the above description, but the undermost layer may be made of any material having a low Young's modulus in addition to metal. For example, a polyimide resin film may be used. The polyimide resin has a low Young's modulus of approximately 3.5 GPa. Besides, the polyimide resin has generally a good affinity for a semiconductor device, and is thus widely used.

### MODIFIED EXAMPLE 1

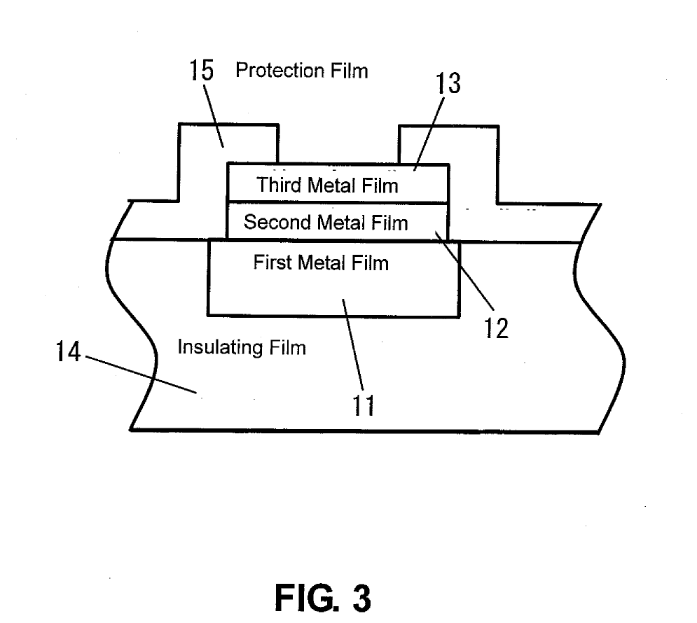

FIG. 3 is a schematic cross-sectional view illustrating Modified Example 1 of the embodiment of the present invention. In the embodiment illustrated in FIG. 1, the first metal film 11 is provided on the insulating film 14, but, as illustrated in FIG. 3, the first metal film 11 may be embedded in the insulating film 14. Then, the second metal film 12 is provided on the embedded first metal film 11. In this case, the insulating film 14 has a groove, and the first metal film 11 is embedded in the groove. The groove has a bottom surface formed into a substantially planar shape. In this structure, the first metal film does not form a step and can thus be formed thick. The strain due to the stress of the second metal film 12 is thus more easily absorbed by the first metal film 11.

### MODIFIED EXAMPLE 2

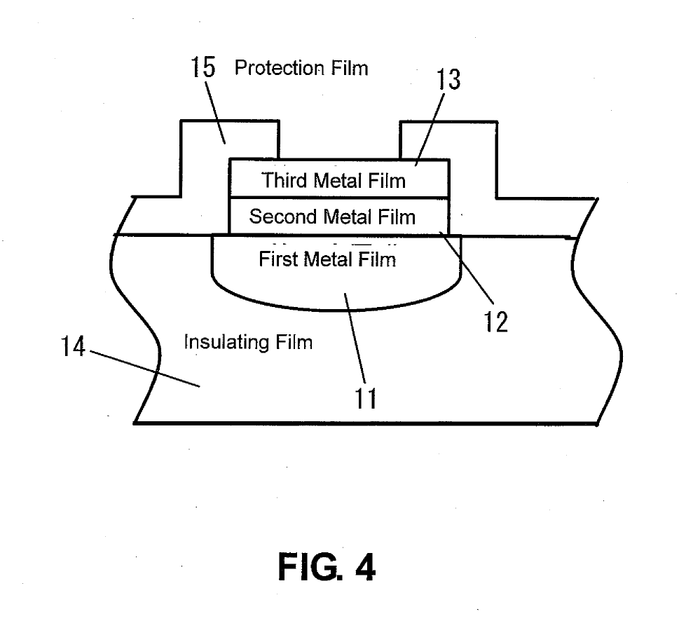

FIG. 4 is a schematic cross-sectional view illustrating Modified Example 2 of the embodiment of the present invention. The structure of FIG. 4 is substantially the same as the structure of FIG. 3, but different in that the bottom surface of the groove of the insulating film 14 is formed so as to be a curve surface that is convex downward or part of a substantially spherical surface as illustrated in FIG. 4, whereas the bottom surface thereof is formed into a substantially planar shape in FIG. 3. In other words, the bottom surface of the first metal film 11 may be formed so as to be a curve surface that is convex downward or part of a substantially spherical surface. This structure prevents stress concentration on corner portions in the bottom surface of the first metal film 11. The strain due to the stress of the second metal film 12 is thus even more easily absorbed by the first metal film 11.

What is claimed is:

1. A semiconductor device having a bonding pad, comprising:
a semiconductor substrate;
an insulating film provided on a surface of the semiconductor substrate;
a first metal film provided on the insulating film;
a second metal film provided on the first metal film;
a third metal film provided on the second metal film; and
a protective film including an opening portion above the third metal film, and covering the first metal film, the second metal film, and the third metal film at portions excluding the opening portion,
wherein the second metal film has a Young's modulus higher than a Young's modulus of the first metal film and a Young's modulus of the third metal film.

2. A semiconductor device according to claim 1, wherein the first metal film and the third metal film are each formed of aluminum.

3. A semiconductor device according to claim 1, wherein the second metal film is formed of copper.

4. A semiconductor device according to claim 1, wherein the second metal film is formed of tungsten.

5. A semiconductor device having a bonding pad, comprising:
a semiconductor substrate;
an insulating film provided on a surface of the semiconductor substrate;
a first metal film placed so as to be embedded in a groove provided in a surface of the insulating film;
a second metal film provided on the first metal film;
a third metal film provided on the second metal film; and
a protective film including an opening portion above the third metal film, and covering the first metal film, the second metal film, and the third metal film at portions excluding the opening portion,
wherein the second metal film has a Young's modulus higher than a Young's modulus of the first metal film and a Young's modulus of the third metal film.

6. A semiconductor device according to claim 5, wherein the groove has a bottom surface formed into a substantially planar shape.

7. A semiconductor device according to claim 5, wherein the groove has a bottom surface formed so as to be one of a curve surface that is convex downward and part of a substantially spherical surface.

8. A semiconductor device according to claim 5, wherein the first metal film and the third metal film are each formed of aluminum.

9. A semiconductor device according to claim 5, wherein the second metal film is formed of copper.

10. A semiconductor device according to claim 5, wherein the second metal film is formed of tungsten.
